(19) United States
(12) Patent Application Publication
(10) Pub. No.: US 2010/0079966 A1
(43) Pub. Date: Apr. 1, 2010

(54) MEMORY MODULE

(75) Inventor: Joong-Hyun BAEK, Hwasung-City (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/564,073

(22) Filed: Sep. 22, 2009

(30) Foreign Application Priority Data
Sep. 30, 2008 (KR) 10-2008-0095753

(51) Int. Cl. H01L 25/16; H05K 7/06

(52) U.S. Cl. 361/783

(57) ABSTRACT

A memory module includes a printed circuit board (PCB), and a plurality of semiconductor packages and a multi-functional package mounted to the PCB. The multi-functional package may have a data processing function and an error correcting function. Thus, the packages may occupy a relatively small area of the PCB in terms of the number of functions that they provide. Thus, the module may be highly integrated.

### CROSS-RELATED APPLICATION

This application claims priority under 35 USC §119 to Korean Patent Application No. 10-2008-0095653, filed on September 30 in the Korean Intellectual Property Office (KIPO).

### BACKGROUND

The inventive concept relates to a memory module. More particularly, the inventive concept relates to a memory module including semiconductor packages.

Electronic devices that include a CPU (central processing unit) are continuously being improved to increase their capacity. In particular, technology has been developed to increase the operating speed and integration of the main memory of the CPU. For example, a bus that is capable of rapidly transmitting/receiving a data packet has been developed. Such a bus may be arranged between the CPU and the main memory to increase input/output speed of data into/from the main memory. Furthermore, memory modules which have relatively high memory (data storage) capacities have been developed as the main memory of CPUs. Memory modules that are widely used basically consist of semiconductor packages mounted to a printed circuit board (PCB), wherein each of the semiconductor packages includes a memory chip.

Such memory modules may be classified as either a single in-lined memory module (SIMM) or a dual in-lined memory module (DIMM). A SIMM has the semiconductor packages mounted on only one surface of a PCB. In contrast, a DIMM has semiconductor packages respectively mounted on both surfaces of a PCB.

There are various other types of semiconductor packages that are mounted to PCBs, i.e., packages other than those that have a memory chip. For instance, some semiconductor packages have an error correction chip configured to correct errors generated when data is processed.

### SUMMARY

According to one aspect of the inventive concept, there is provided a memory module having a printed circuit board (PCB), a plurality of semiconductor packages mounted to the PCB, and a multi-functional package mounted to the PCB.

According to another aspect, the semiconductor packages are configured to perform a specified function in the module, and the multi-functional package has at least one chip configured to perform at least two functions in the module. At least one of functions performed by the multi-functional package is different from the specified function performed by the semiconductor packages.

According to another aspect of the inventive concept, the semiconductor packages are configured to all perform substantially the same specified function. The multi-functional package has at least one chip configured to perform at least two functions in the module.

### BRIEF DESCRIPTION OF THE DRAWINGS

A memory module embodied in accordance with the inventive concept will be more clearly understood from the following detailed description thereof made in conjunction with the accompanying drawings, of which:

FIG. 1 is a plan view of an embodiment of a memory module in accordance with the inventive concept;

FIG. 2 is a bottom view of the memory module of FIG. 1;

FIG. 3 is a cross-sectional view of the memory module of FIG. 1;

FIG. 4 is a cross-sectional view of a multi-functional package of the memory module of FIG. 1;

FIG. 5 is a cross-sectional view of another example of a multi-functional package of an embodiment of a memory module in accordance with the inventive concept;

FIG. 6 is a plan view of another embodiment of a memory module in accordance with the inventive concept;

FIG. 7 is a cross-sectional view of a multi-functional package of the memory module of FIG. 6;

FIG. 8 is a plan view of another embodiment of a memory module in accordance with the inventive concept;

FIG. 9 is a cross-sectional view of the memory module of FIG. 8;

FIG. 10 is a plan view of still another embodiment of a memory module in accordance with the inventive concept; and

FIG. 11 is a cross-sectional view of the memory module of FIG. 10.

### DETAILED DESCRIPTION OF THE PREFERRED EMBODIMENTS

Various examples of a memory module embodied in accordance with the inventive concept will be described more fully hereinafter with reference to the accompanying drawings. Like reference numerals are used to designate like elements throughout the drawings. Also, in the drawings, the sizes and relative sizes of components, layers and structures (elements) may be exaggerated for clarity. In particular, cross-sectional views are schematic in nature and thus illustrate at least some of the elements in an idealized manner. As such, the shapes of at least some of the elements in an actual memory module in accordance with the inventive concept may vary from those illustrated due, for example, to manufacturing techniques and/or tolerances.

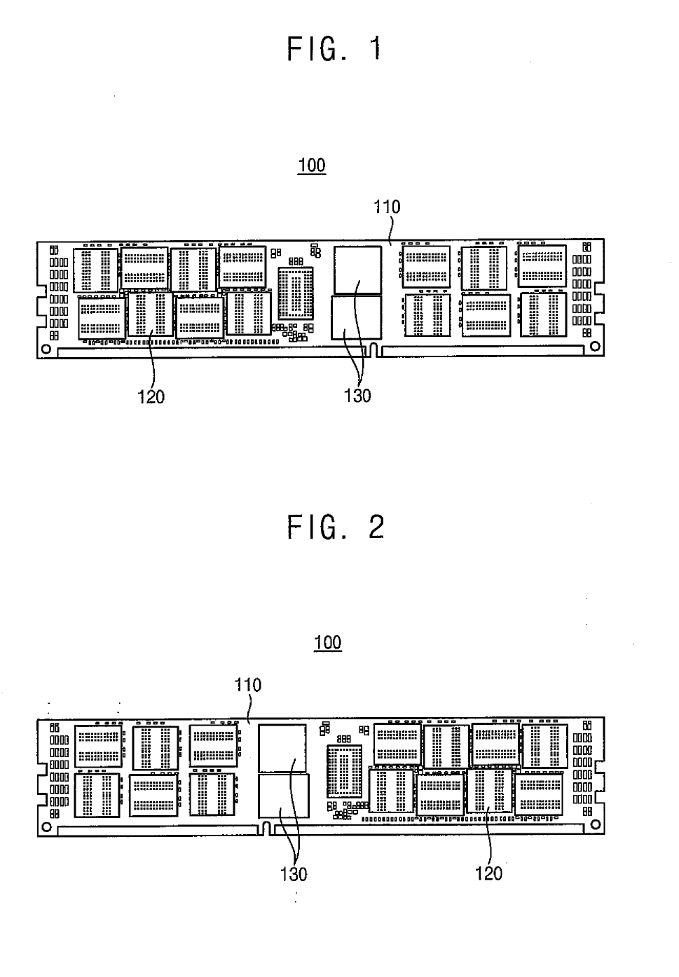

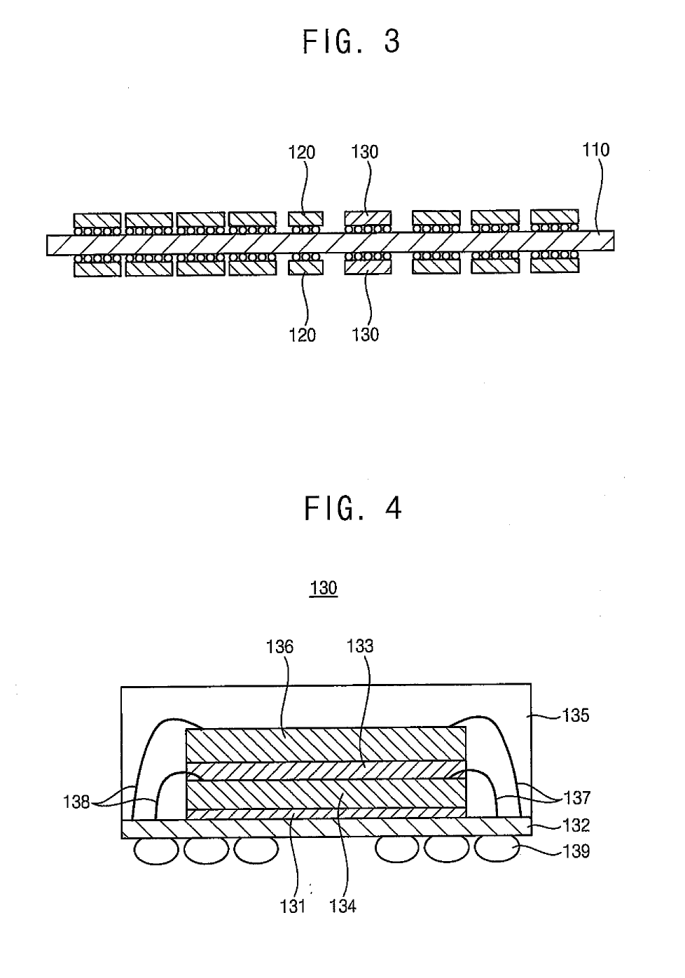

Referring now to FIGS. 1 to 3, one example of a memory module 100 in accordance with the inventive concept includes a PCB 110, a plurality of semiconductor packages 120, and multi-functional packages 130. The PCB 110 and more specifically, a substrate of the PCB, has a rectangular cross section as shown in FIG. 3. Also, the PCB has at least one circuit pattern integrated with its substrate.

Each of the semiconductor packages 120 may include a package substrate (not shown), at least one semiconductor chip (not shown), conductive connecting members (not shown) and a molded member (not shown). The semiconductor chip may be mounted on an upper surface of the package substrate. The semiconductor chip and the package substrate may be electrically connected with each other via the conductive connecting members. The molded member may be disposed on the package substrate over the conductive connecting members and the semiconductor chip. That is, the molded member may encapsulate the chip on the substrate.

As an example, the semiconductor chip may comprise a DRAM. In the case in which one or more of the semiconductor packages 120 comprises a DRAM, active elements, passive elements, etc., as well as the DRAM may be mounted to the PCB 110.

However, the semiconductor chip may comprise other types of memory devices besides a DRAM. Also, each of the semiconductor packages 120 may respectively be a chip scale package (CSP) having one semiconductor chip, a dual stack package (DSP) having two semiconductor chips, or a quad stack package (QSP) having four semiconductor chips.

Referring to FIG. 4, each of the multi-functional packages 130 performs at least two functions. For example, the multi-functional package 130 may perform a data processing function and an error correcting function.

In the present embodiment, and as an example, the multi-functional package 130 includes a package substrate 132, a semiconductor chip 134, an error correcting chip 136, input lines 137, output lines 138, a molded member 135 and external terminals 139. The package substrate 132 may have input pads (not shown) and output pads (not shown).

The package substrate 132 is mounted on the PCB 110. The semiconductor chip 134 is disposed on an upper surface of and is attached to the package substrate 132. For example, the semiconductor chip 134 may be attached to the package substrate 132 by a first adhesive 131 interposed between the package substrate 132 and the chip 134.

In this embodiment, the semiconductor chip 134 is configured to process data, i.e., the semiconductor chip 134 provides/performs a data processing function of the multi-functional package 130. The data processing function of the semiconductor chip 134 may be substantially the same as that of the chips of the semiconductor packages 120. Thus, the semiconductor chip 134 of the multi-functional package 130 may have a structure substantially the same as those of the semiconductor chips of the semiconductor packages 120.

Also, in this embodiment, the semiconductor chip 136 is an error correcting chip. In this case, the error correcting chip 136 is configured to correct errors generated when the semiconductor chip 134 of the multi-functional package 130 and the semiconductor chips of the semiconductor packages 120 process data. The error correcting chip 136 is stacked on an upper surface of and is attached to the semiconductor chip 134. For example, the error correcting chip 136 is attached to the upper surface of the semiconductor chip 134 by a second adhesive 133. Also, the error correcting chip 136 and the semiconductor chip 134 may have substantially the same size.

The input lines 137 electrically connect the input pads of the package substrate 132 to the semiconductor chip 134 and the error correcting chip 136. The input lines 137 may be gold wires. In one example, two input lines 137 extend from a single input pad to the semiconductor chip 134 and the error correcting chip 136, respectively. Thus, an input signal inputted to the single input pad may be transmitted to the semiconductor chip 134 and the error correcting chip 136 through the two input lines 137.

The output lines 138 electrically connect the semiconductor chip 134 and the error correcting chip 136 to the output pads of the package substrate 132. The output lines 138 may also be gold wires. In the example shown in FIG. 4, the two output lines 138 extend from the semiconductor chip 134 and the error correcting chip 136 to two output pads, respectively. Thus, output signals outputted from the semiconductor chip 134 and the error correcting chip 136 may be transmitted to the output pads, respectively, through the separate output lines 138.

The molded member 135 is disposed on the package substrate 132 and covers (and more specifically, encapsulates) the semiconductor chip 134, the error correcting chip 136, the input lines 137 and the output lines 138. To this end, the molded member 135 may be of an epoxy molding compound (EMC).

The external terminals 139 are mounted on the lower surface of the package substrate 132. For example, the external terminals 139 are solder balls. In any case, the external terminals 139 are electrically connected to the input lines 137 and the output lines 138. Furthermore, the external terminals 139 are mounted to the PCB 110 and are electrically connected to a circuit pattern of the PCB.

According to the inventive concept as described so far in connection with the embodiment of FIGS. 1-4, even though the memory module 100 is provided with an extra function (i.e., a function in addition to that provided by the chips of packages 120), the semiconductor packages can occupy a relatively small area of the PCB 110 because at least one of the packages (package 130) that includes a chip of the same type as the rest of the packages also has ,a chip that provides the module 100 with an additional function.

Referring now back to FIGS. 1 and 2, the memory module 100 of this embodiment requires four error correcting chips 136. Therefore, a respective first pair of the multi-functional packages 130 may be disposed on the upper surface of the PCB 110 and a respective second pair of the multi-functional packages 130 may be disposed on the lower surface of the PCB 110.

Moreover, the memory module 100 according to the inventive concept may be embodied as a dual in-lined memory module (DIMM) in which the semiconductor packages 120 and the multi-functional packages 130 are mounted on both surfaces of the PCB 110. Alternatively, the memory module may be embodied as a fully buffered dual in-lined memory module (FBDIMM) having an advanced memory buffer (AMB) that transmits external signals to the semiconductor packages 120 and the multi-functional packages 130. Furthermore, the memory module 100 may be a single in-lined memory module (SIMM) having the semiconductor packages 120 and the multi-functional packages 130 mounted on only one surface of the PCB 110.

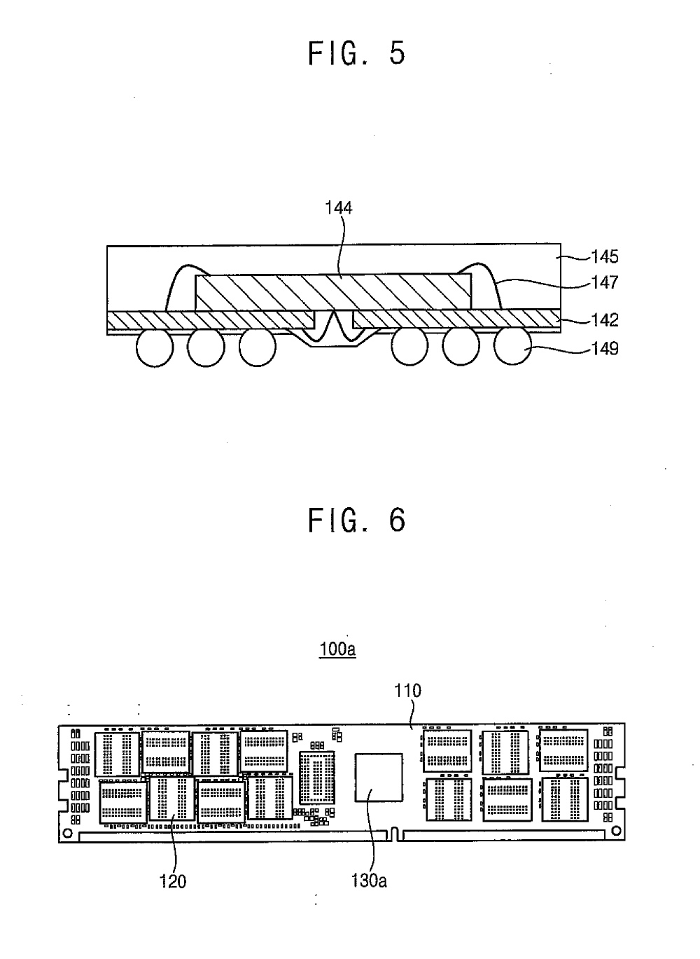

FIG. 5 is a cross-sectional view of another multi-functional package which may be employed by a memory module in accordance with the inventive concept.

Referring to FIG. 5, the multi-functional package 140 of this example includes a package substrate 142, a single multi-functional chip 144, conductive connecting members 147, a molded member 145 and external terminals 149.

The multi-functional chip 144 may be configured to provide a data processing function and an error correcting function of correcting errors in generated data. Thus, the multi-functional chip 144 may have data processing pads and error correcting pads. The conductive connecting members 147 electrically connect the pads of the multi-functional chip 144 and the package substrate 142. The molded member 145 is disposed on the package substrate 142 and covers (encapsulates) the conductive connecting members 147 and the multi-functional chip 144. The external terminals 149 are mounted on a lower surface of the package substrate 142. The external terminals 149 are electrically connected to a circuit pattern of the PCB 110 in a module which employs the package having the single multi-functional chip 144.

According to this example, as was mentioned above, a data processing function and an error correcting function are provided by a single multi-functional chip. Thus, this package may be employed instead of the package 130 in any of the embodiments described above. Also, a memory module including the multi-functional package(s) of FIG. 5 may be thinner than that of a corresponding memory module employing a semiconductor package of FIG. 4, but may be wider due to the fact that the package of FIG. 5 would obviously require a large footprint on the PCB than the package of FIG. 4.

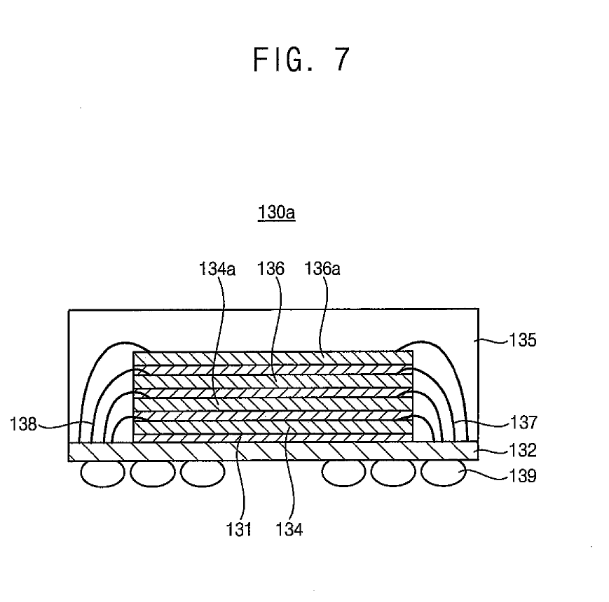

Another embodiment of a memory module in accordance with the inventive concept will now be described with reference to FIGS. 6 and 7.

The embodiment of the memory module 100a of FIGS. 6 and 7 and other examples thereof are substantially the same as those described with respect to and shown in FIGS. 1-3, except with regard to the multi-functional package(s). The memory module 100a of this embodiment includes two multi-functional packages 130a mounted on the sides of the PCB 110, respectively. As mentioned above, the memory module may require four error correcting chips. Thus, in this embodiment, as distinguished from that of FIGS. 1-3, each multi-functional package 130a of the memory module 100a has two error correcting chips 136 and 136a.

In addition, the multi-functional package 130a may include a package substrate 132, two semiconductor chips 134 and 134a, input lines 137, output lines 138, a molded member 135 and external terminals 139. The package substrate 132 has input pads and output pads. The two semiconductor chips 134 and 134a may be stacked on the package substrate 132. The two error correcting chips 136 and 136a may be stacked on the upper semiconductor chip 134a. The input lines 137 electrically connect the input pads to the semiconductor chips 134 and 134a and the error correcting chips 136 and 136a. The output lines 138 electrically connect the output pads to the semiconductor chips 134 and 134a and the error correcting chips 136 and 136a. The molded member 135 is disposed on the package substrate 132 and covers (encapsulates) the semiconductor chips 134 and 134a, the error correcting chips 136 and 136a, the input lines 137 and the output lines 138. The external terminals 139 are mounted on a lower surface of the package substrate 132.

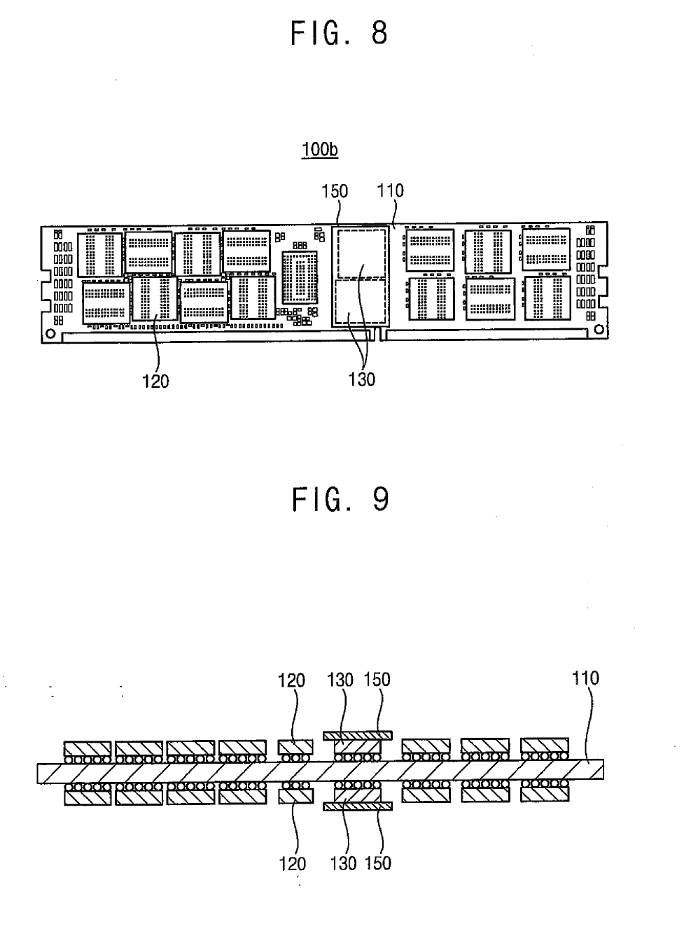

FIGS. 8 and 9 illustrate another embodiment of a memory module in accordance with the inventive concept.

The memory module 100b of this embodiment is substantially the same as the memory Module 100 of FIGS. 1-3 (or any of the other examples described above) except that the memory module 100b additionally includes a heat sink 150 contacting the multi-functional package(s). As an example, the module 100b will be described as employing the multi-functional packages 130 of the type shown in FIG. 4, but the module 100b may alternatively employ multi-functional packages of the types shown in FIGS. 5 and 7.

The heat sink 150 may be disposed on upper surfaces of the multi-functional packages 130, as shown in the figures, i.e., opposite the sides thereof at which the multi-functional packages are mounted to the PCB 110. Furthermore, the heat sink 150 may be fixed to the PCB 110 by a clip (not shown).

As mentioned above, the multi-functional package 130 performs several functions, e.g., data processing and error correcting. Thus, the multi-functional package 130 may generate larger amounts of heat than any of the semiconductor packages 120. With this in mind, the heat sink 150 contacts the multi-functional packages 130 so that the heat in the multi-functional packages 130 may be rapidly dissipated through the heat sink 150.

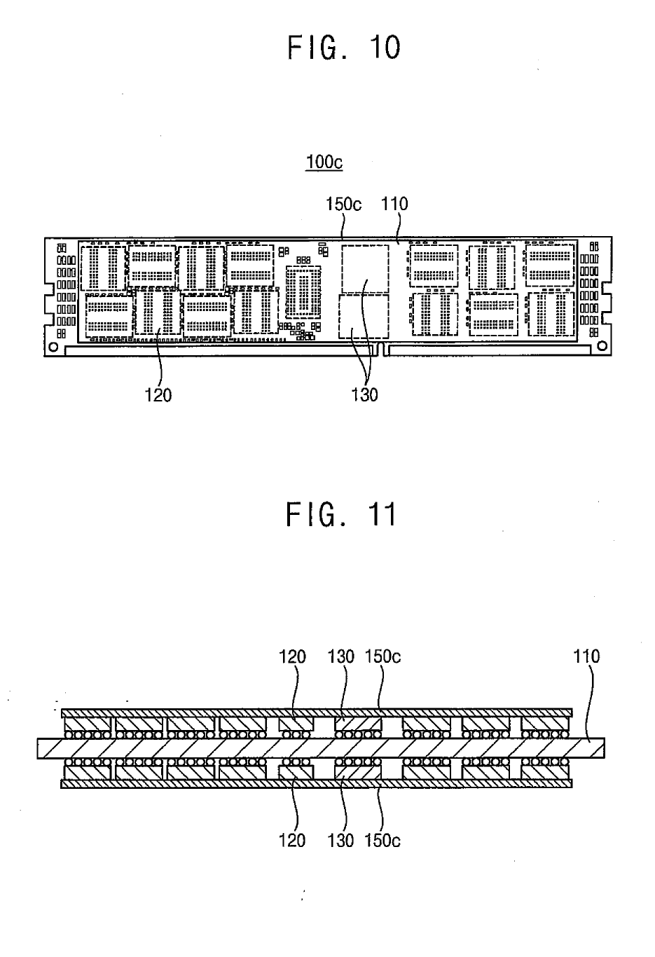

Another embodiment of a memory module in accordance with the inventive concept will now be described with reference to FIGS. 10 and 11.

The memory module 100c of this embodiment is substantially the same as those of the previously described embodiments and examples except for a heat sink 150c. As an example, the module 100c will be described as employing the multi-functional packages 130 of the type shown in FIG. 4, but the module 100b may alternatively employ multi-functional packages of the types shown in FIGS. 5 and 7.

Referring to FIGS. 10 and 11, the heat sink 150c is disposed on upper surfaces of the semiconductor packages 120 as well as on the upper surfaces of the multi-functional packages 130. Thus, heat in both the semiconductor packages 120 and in the multi-functional packages 130 may be rapidly dissipated through the heat sink 150c.

According to the embodiments of the inventive concept as described above, the memory module includes a multi-functional package. The chip or chips of the multi-functional package may be configured to perform a data processing function and an error correcting function. Thus, the package may occupy small area of the PCB considering the number of functions that the package performs for the module. Accordingly, the module can be densely integrated by practicing the inventive concept.

Furthermore, heat generated in the multi-functional package may be rapidly dissipated through the heat sink.

Finally, embodiments of the inventive concept have been described herein in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiments described above but by the following claims.

What is claimed is:

1. A memory module comprising:
a printed circuit board (PCB);
a plurality of semiconductor packages mounted to the PCB, the semiconductor packages having chips configured to perform a specified function in the module; and
a multi-functional package mounted to the PCB and having at least one chip, wherein said at least one chip is configured to perform at least two functions in the module, at least one of said functions being different from the specified function performed by the chips of the semiconductor packages.

2. The memory module of claim 1, wherein the chips of the semiconductor packages are memory chips that store data, the PCB electrically connects the semiconductor packages and the multi-functional package so that data stored in the memory chips are transmitted to the multi-functional package via the PCB, and the at least one chip of the multi-functional package is configured to perform a data processing function of processing data input thereto from the memory chips of the semiconductor packages and to perform an error correcting function of correcting errors in the processing of the data.

3. The memory module of claim 2, wherein the at least one chip of the multi-functional package comprises a semiconductor chip configured to perform the data processing function, and an error correcting chip stacked on the semiconductor chip and configured to perform the error correcting function, and the multi-functional package further comprises:
a package substrate mounted to the PCB and to which the semiconductor chip is mounted;
input lines electrically connecting the package substrate to the semiconductor chip and the error correcting chip;
output lines electrically connecting the semiconductor chip and the error correcting chip to the package substrate; and
a molded member disposed on the package substrate and covering the semiconductor chip, the error correcting chip, the input lines and the output lines.

4. The memory module of claim 2, wherein the at least one chip of the multi-functional package is a single multi-functional chip configured to perform both the data processing function and the error correcting function, and the multi-functional package further comprises:
a package substrate mounted to the PCB and to which the multi-functional chip is mounted; and
conductive connecting members electrically connecting the multi-functional chip to the package substrate; and
a molded member disposed on the package substrate and covering the multi-functional chip and the conductive connecting members.

5. The memory module of claim 1, wherein some of the packages are disposed one side of the PCB, and others of the packages are disposed on the other side of the PCB.

6. The memory module of claim 1, further comprising a heat sink.

7. The memory module of claim 6, wherein the heat sink contacts a surface of the multi-functional package opposite a side of the multi-functional package at which the multi-functional package is mounted to the PCB.

8. The memory module of claim 7, wherein the heat sink contacts surfaces of the multi-functional package and the semiconductor packages opposite sides thereof at which the packages are mounted to the PCB.

9. A memory module comprising:
a printed circuit board (PCB);
a plurality of semiconductor packages mounted to the PCB, the semiconductor packages each having a chip, and the chips being configured to all perform substantially the same specified function; and
a multi-functional package mounted to the PCB and having at least one chip, wherein said at least one chip is configured to perform at least two functions in the module.

10. The memory module of claim 9, the PCB electrically connects the semiconductor packages and the multi-functional package.

11. The memory module of claim 10, wherein one of the at least two functions performed by the at least one chip of the multi-functional package is the same as the specified function performed by the chips of the semiconductor packages.

12. The memory module of claim 9, wherein the at least one chip of the multi-functional package comprises discrete chips configured to perform the at least two chips, respectively.

13. The memory module of claim 12, wherein the discrete chips include a semiconductor chip configured to perform a data processing function, and an error correcting chip stacked on the semiconductor chip and configured to perform an error correcting function in which errors in processed data are corrected.

14. The memory module of claim 9, wherein the at least one chip of the multi-functional package is a single multi-functional chip configured to perform the at least two functions.

15. The memory module of claim 14, wherein the single multi-functional chips is configured to perform a data processing function and an error correcting function in which errors in processed data are corrected.
